(19) United States
(12) Patent Application Publication
(10) Pub. No.: US 2006/0158257 A1
(43) Pub. Date: Jul. 20, 2006

(54) Semiconductor circuit

(75) Inventors: Masahiro Fujimoto, Yamaguchi (JP); Ryuji Oyama, Yamaguchi (JP); Masahide Kondo, Yamaguchi (JP); Hiroshi Oda, Yamaguchi (JP)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: UBE INDUSTRIES, LTD., Yamaguchi (JP)

(21) Appl. No.: 10/547,467

(22) PCT Filed: Mar. 22, 2004
(86) PCT No.: PCT/JP04/03850

§ 371 Date: Aug. 30, 2005

(30) Foreign Application Priority Data
Mar. 24, 2003 (JP) 2003-080976

(51) Int. Cl. H03F 3/68; H03F 3/04

(52) U.S. Cl. 330/299

(57) ABSTRACT

Second transistors working as temperature-monitoring elements are disposed in the vicinity of the respective first transistors (HBT cells) connected in parallel to amplify an RF signal and at positions where their thermal environments are substantially the same. Each of the second transistors is connected between its collector and its base to thereby constitute a diode through which the current rises as the temperature increases. The collectors of the second transistors are connected with a DC power supply through respective first resistors, and their emitters are grounded through respective second resistors. Further, their bases are connected with the bases of the respective first transistors through respective first inductors.

### TECHNICAL FIELD

The present invention relates to a semi-conductor circuit in which a plurality of bipolar transistors are connected in parallel to each other, and more particularly to a semi-conductor circuit having the function of amplifying a signal by use of hetero-junction bipolar transistors.

### BACKGROUND ART

In general, a hetero-junction bipolar transistor (hereinafter referred to as an HBT) is liable to show a positive correlation between the collector current and the temperature, thus exhibiting thermal instability. Particularly, an HBT power amplifier in which many HBT cells are connected in parallel has the problems of an unstable operation that the current and heat are concentrated on some of the HBT cells and of the failure of the transistors caused thereby.

FIG. 7 is a configuration showing a conventional amplifier circuit. Referring to FIG. 7, reference numerals 11 to 14 denote hetero-junction bipolar transistors (HBT cells); 101 denotes a power amplifier circuit unit; 102 denotes a matching circuit; 103 denotes an antenna; reference symbols C1 to C4 represent the first to the fourth capacitors, respectively; IN1 represents a high-frequency (RF) input port; IN2 represents a DC power supply input port; OUT represents an output port; Lc represents a choke inductor; Rb1 to Rb4 represent base ballasting resistors; Vcc represents a power supply voltage; and Wb represents a bias line.

The matching circuit 102 is used for feeding to the antenna 103 under the optimum impedance condition. Further, reference symbol R10 represents a resistor connected with the DC supply input port IN2, and reference numeral 20 denotes a hetero-junction bipolar transistor the collector of which is connected with its base. In addition, the bias line Wb is defined as the line leading from the input port IN2 to the bases of the HBT cells 11 to 14 through the base ballasting resistors Rb1 to Rb4, respectively.

In order to prevent the instability caused by the thermal effect of the above-mentioned amplifier circuit, the power amplifier circuit unit 101 is equipped with the base ballasting resistor Rb1 connected in series to the base of the HBT 11, and the unit is devised to thereby cause negative feedback to be induced against the current increase, namely, the current concentration in the HBT 11. For example, U.S. Pat. No. 5,529,648 discloses an HBT power amplifier in which the base current increases with an increase in the collector current of the HBT 11, thereby increasing the voltage drop of the base ballasting resistor Rb1, while causing the voltage of the base of the HBT 11 to drop because the other end of the base ballasting resistor Rb1 is connected with the constant voltage source, thereby preventing the thermal instability in the HBT 11.

The conventional amplifier circuit is arranged as mentioned above. Therefore, in order to have the base ballasting resistors to work effectively, there is an issue of the design problem that the optimum values of the resistances thereof are chosen depending on the designs of the size and the bias point of the emitter thereof.

Moreover, for the applications of mobile radio communication systems, the mobile terminals are required to work with batteries, and to operate by use of a low-voltage power supply. However, when a base ballasting resistor is used therein, it is difficult for the mobile terminals to operate well. In order to prevent the thermal instability by use of the above-mentioned base ballasting resistor, the resistance thereof should be chosen such that the temperature variation of the HBT is properly compensated. Further, the base ballasting resistor is inserted in series to the HBT with respect to the DC power supply; accordingly, the additional voltage is required for the DC power supply. Briefly, when the base ballasting resistance is set to a high value so as to obtain a sufficient effect of the compensation of the temperature variation of the HBT, the DC power supply voltage must be set to a high value. This may be a problem in operating the communication system with a low-voltage power supply.

The present invention has been accomplished to solve the above-mentioned problem. An object of the present invention is to provide a semi-conductor circuit in which a large number of bipolar transistors, specifically HBT cells, are connected in parallel to each other to be capable of efficiently preventing the occurrence of the thermal instability and working with a low power supply voltage in a comparatively simple circuitry.

### DISCLOSURE OF THE INVENTION

The inventors have studied thoroughly, and found the semi-conductor circuit of the present invention described below. Namely, the semi-conductor circuit of the present invention includes: a plurality of first transistors, connected in parallel, for amplifying an RF signal; and a plurality of diodes, which are respectively placed in the vicinity of the first transistors under the substantially same temperature, and through which the current increases as the temperature rises; and the anode of the diode is connected with a DC power supply through a first resistor, while the cathode of the diode is connected to the ground through a second resistor, and the anode thereof controls the collector current of the first transistor by connecting with the base of the first transistor.

In this way, even if a temperature rises in one of the plurality of bipolar transistors due to an increase of the collector current, the voltage drop of the first resistor is increased, thereby lowering the voltage of the anode. Thus, the base voltage of the bipolar transistor connected with the anode also may be lowered, thereby preventing the thermal instability of the bipolar transistors.

Furthermore, because the resistors corresponding to the base ballasting resistors Rb1 to Rb4 of the conventional amplifier circuit (FIG. 7) are not used, the amplifier circuit of the present invention could work with a lower power supply voltage as compared with the conventional technology.

Additionally, the semi-conductor circuit may be arranged such that the diode is constructed of a second transistor the collector and the base of which are directly connected.

Further, the semi-conductor circuit may be arranged such that the first transistor and the second transistor are hetero-junction bipolar transistors.

Also, the semi-conductor circuit may be arranged such that the base of the first transistor and the anode of the diode are connected through an element exhibiting a high impedance at the frequency of RF signals.

In addition, the semi-conductor circuit may be arranged such that the base of the first transistor and the base of the second transistor are connected through an element having a high impedance at the frequency of the RF signals.

Moreover, the semi-conductor circuit may be arranged such that the element having a high impedance is an element selected from the group consisting of an inductor, a resistor, and an inductor connected in series with a resistor.

### BRIEF DESCRIPTION OF THE DRAWINGS

FIG. 1 is a configuration of the amplifier circuit in accordance with embodiment 1 of the present invention;

FIG. 2 is a plan view schematically showing the layout of the amplifier circuit of FIG. 1;

FIG. 3 is a cross-sectional view taken along the line A-A of FIG. 2;

FIG. 4 is a graph comparing the simulation results of the temperature variation of the collector current Icc that flows through the first transistors of the conventional amplifier circuit (a) of the embodiment 1;

FIG. 5 is a configuration of an amplifier circuit in accordance with embodiment 2 of the present invention;

FIG. 6 is a graph comparing the simulation result of the temperature variation of the collector current Icc that flows through the first transistors of the conventional amplifier circuit (b) of the embodiment 2; and

FIG. 7 is a configuration of a conventional amplifier circuit.

### BEST MODE FOR CARRYING OUT THE INVENTION

An embodiment of the present invention will now be described with reference to the drawings in order to make description in further details of the present invention.

### Embodiment 1

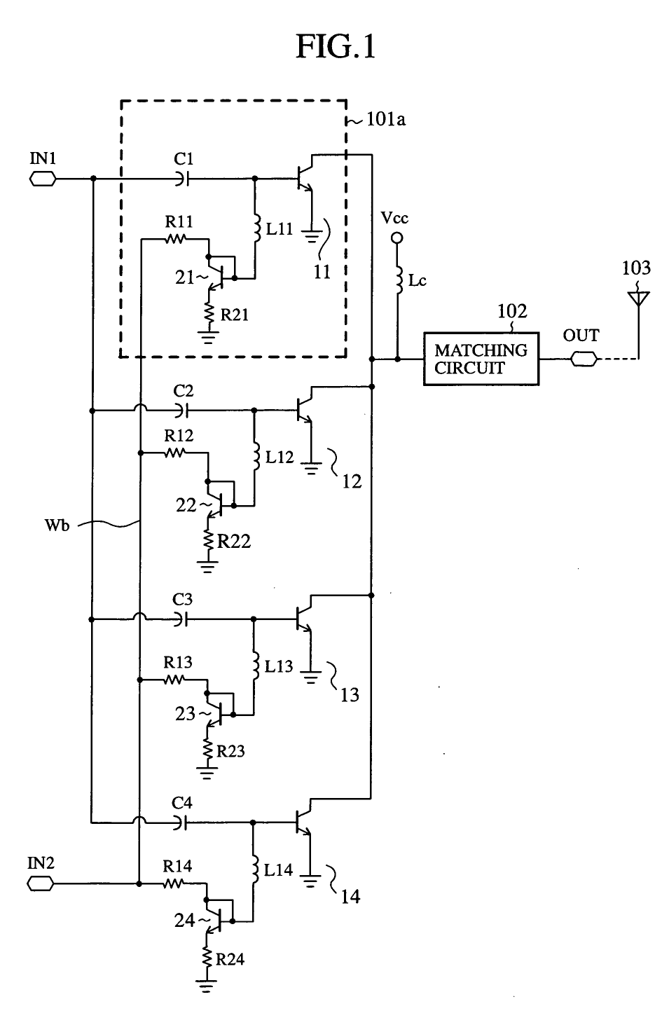

FIG. 1 is a configuration of an amplifier circuit according to embodiment 1 of the present invention, the amplifier circuit having a configuration in which a plurality of transistors are connected in parallel. In FIG. 1, reference numerals 11 to 14 denote hetero-junction bipolar transistors (HBT cells) each constituting a first transistor; 21 to 24 denote second transistors of the HBT cells each constituting a temperature-monitoring element; 101a denotes a power amplifier circuit unit; 102 denotes a matching circuit; numeral 103 denotes an antenna; reference symbols C1 to C4 represent the first to fourth capacitors, respectively; IN1 represents a high-frequency (RF) input port; IN2 represents a constant-voltage DC power input port; OUT represents an output port; L11 to L14 represent first inductors each constituting a high impedance element; Lc represents a choke inductor; R11 to R14 represent resistors (first resistors); R21 to R24 represent similarly resistors (second resistors); Vcc represents a power supply voltage; and Wb represents a bias line. The bias line Wb herein is defined as the line leading from the input port IN2 to the bases of the HBT cells 11 to 14 through the resistors R11 to R14, the first transistors 11 to 14, and the first inductors L11 to L14. In addition, the function of the matching circuit 102 is the same as the one described in the background art.

This amplifier is constructed of a semi-conductor circuit in which four hetero-junction bipolar transistors are connected in parallel; however, the amplifier can be composed of connecting (n)HBT cells (n is any positive integer) in parallel therein. In the vicinity of each of the HBT cells 11 to 14, for example, the HBT 11 within a power amplifier circuit unit 101a is placed with a second transistor 21 constituting a temperature-monitoring element 21 (Hereinafter, the second transistor corresponding to the temperature-monitoring element will be designated by the same numeral.) and connected from the base of the HBT 11 through the first inductor L11. The collector of this HBT 11 is connected with the output port OUT through the matching circuit 102, and the emitter is grounded through the resistor R21. Moreover, the RF input port IN1 is connected with the node between the base of the HBT 11 and the first inductor L11 through the first capacitor C1.

In the embodiment 1, for the power amplifier circuit unit 101a, the second transistor 21 is realized as a diode, which is constructed by short-circuiting the base and the collector of the HBT, and is combined with the resistor R 11; consequently, there appears the voltage drop of the base of the second transistor 21 when the temperature rises. That is, the second transistor is an HBT, thus causing the base current to increase with an increase in the temperature. However, because the collector thereof is connected with the constant voltage source of the DC input power supply IN2 through the resistor R11, the increase of the voltage drop corresponding to the increase of the current is caused at the resistor R11, which results in the reduction of the voltage of the collector thereof. Herein, the resistor R21 is provided between the emitter of the second transistor 21 and ground. In addition, HBT cells such as of AlGaAs/GaAs and InGaP/GaAs are employed for each of the above HBT cells.

As shown in FIG. 1, the second transistor 21 constituting the temperature-monitoring element 21 is connected with the HBT 11 the base of which is located in the vicinity of the second transistor 21 through the first inductor L11, and is disposed such that the second transistor 21 is thermally coupled to the HBT 11 constituting the first transistor. Moreover, the inductance of the first inductor L11 is set to the value with which the second transistor 21 is seen as higher impedance from the input of the first transistor to thereby prevent the leakage of the high frequency.

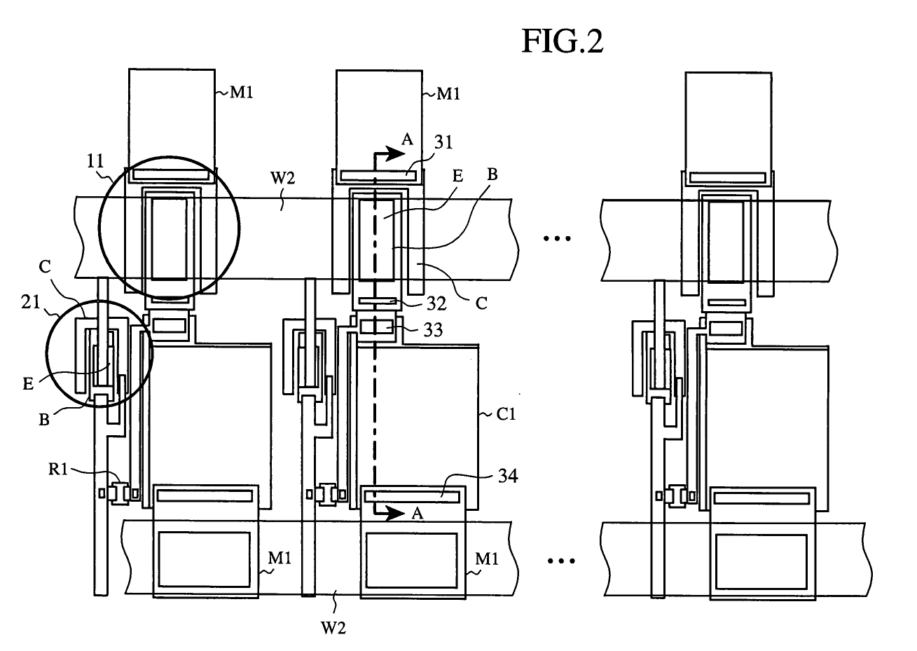

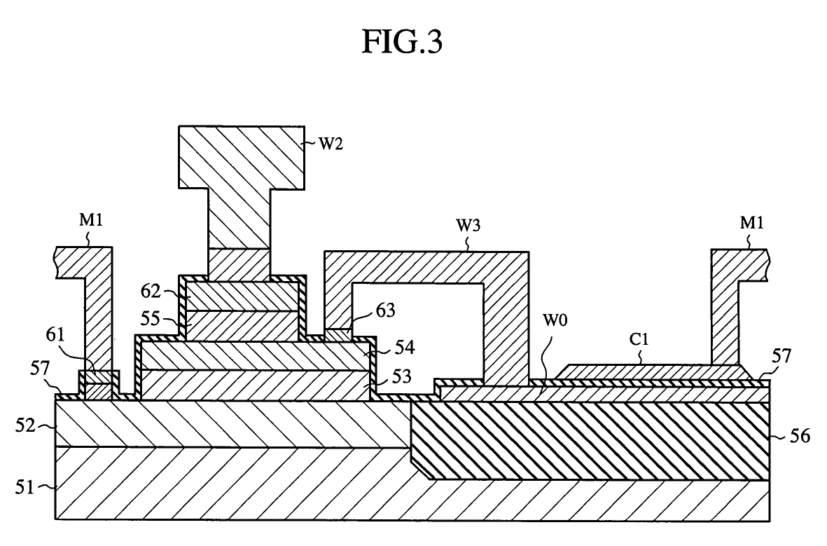

FIG. 2 is a plan view schematically showing the case in which the HBT devices composed by InGaP/GaAs, for example, are used. FIG. 3 is a cross-sectional view taken along the line A-A of FIG. 2. In the drawings, reference symbol C1 represents a first capacitor; M1 represents a first metal; and W0 to W3 represent wirings 0 to 3, respectively. The wiring W3 consists of the first metal, while the wiring W2 consists of the second metal. Reference numerals 31 to 34 denote via holes; 51 denotes a semi-conductor GaAs substrate; 52 denotes an n⁺-GaAs sub-collector layer; 53 denotes an n-GaAs collector layer; 54 denotes a p⁺-GaAs base layer; 55 denotes an n-InGaP emitter layer; 56 denotes an ion-implanted device-isolation area; 57 denotes an insulation film, and becomes a capacitive insulation film under the first capacitance C1; 61 denotes a collector; 62 denotes an emitter; and 63 denotes a base.

In the device fabrication, epitaxial layers serving as a device area, that is, the collector layer 53, the base layer 54, and the emitter layer 55 are stacked from the side of the substrate 51 in this order. In order to reduce the contact resistance of the electrode, a highly doped low-resistance layer is provided over the emitter layer 55 and under the collector layer 53, respectively. An isolation between devices, namely, the device-isolation area 56 is typically formed by use of a high-resistance layer formed by means of an ion implantation with protons and so on.

The first metal M1 is electrically connected with the collector through the first via hole 31 opened through the insulation film 57 on the sub-collector layer 52, while it is electrically connected with the top of the first capacitance C1. Further, the wiring W3 is electrically connected with the base through the second via hole 32 opened through the insulation film 57 on the base layer 54, and further, is electrically connected with the wiring W0 through the third via hole 33 opened through the insulation film 57 on the wiring W0. In addition, the first metal M1, the wiring W3 formed of the same material, and the wiring W2 electrically connected with the second metal are formed through the first and second inter-layer dielectrics (not shown).

The operation will now be described below.

If the current concentrates in the HBT 11 among the plurality of HBT cells 11 to 14 (first transistors) connected in parallel, there arises the possibility that positive feedback locally occurs, thereby causing the HBT to exhibit thermal instability. As prevention measures against the thermal instability, the temperature-monitoring element 21 that is the second transistor working as a diode by short-circuiting the collector and base, and the resistor R11 inserted between the monitoring element and the DC power input port IN2 that is a constant-voltage source may bring about a voltage drop corresponding to an increase of the collector current. As a result, the base voltage of the temperature-monitoring element (second transistor) 21 is lowered, and the lower voltage is applied to the base of the HBT 11 to thus prevent the increase of the collector current of the HBT 11; in this way, the occurrence of the thermal instability in the amplifier circuit can be efficiently prevented.

In this case, high impedance of the first inductors L11 to L14 prevents the leakage of a high frequency component.

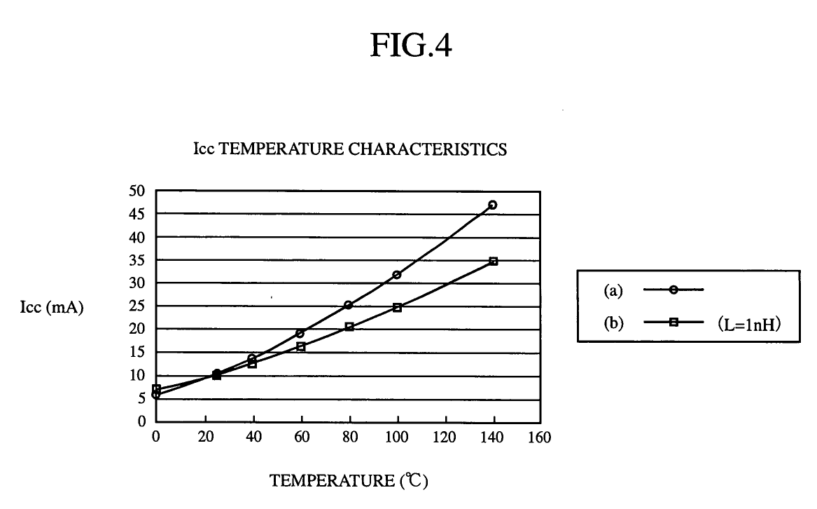

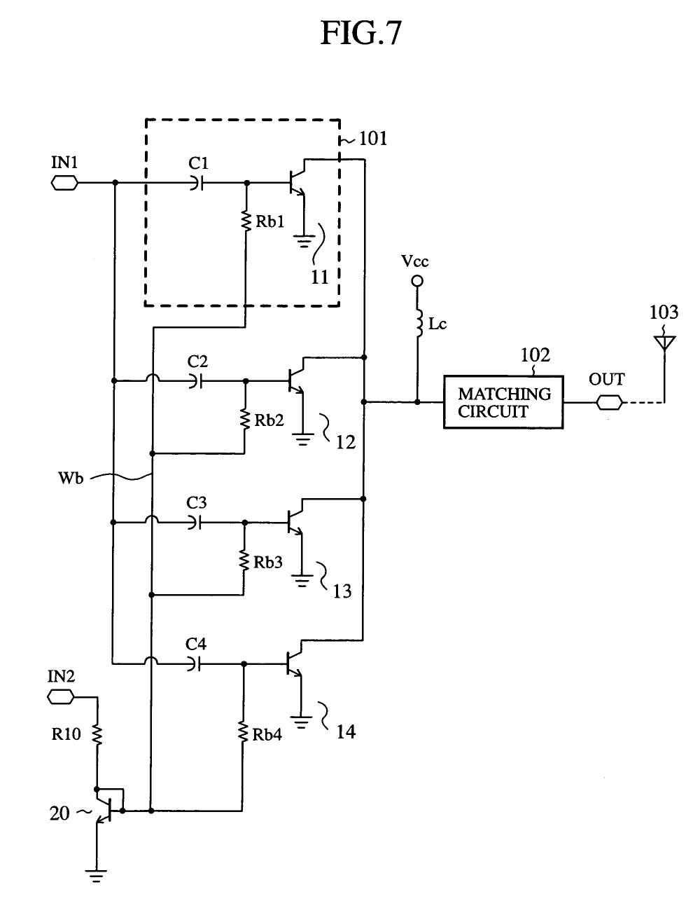

FIG. 4 shows the temperature variation of the collector current Icc that flows through the first transistors 11 to 14. The figure compares the results (a) where the value of the base ballasting resistor is set to 60Ω in the conventional amplifier circuit (FIG. 7) with the simulation result (b) of the circuit (FIG. 1) in accordance with the embodiment 1, where the second transistors 21 to 24 of the temperature-monitoring elements 21 to 24 arranging the first inductors L11 to L14, respectively, are provided in the vicinity of the first transistors 11 to 14, respectively. In this simulation, it is assumed that the temperature rises in one of the four first transistors constituting the HBT cells 11 to 14; it is further assumed that the temperature of the second transistor adjoining thereto is the same temperature.

As is apparent from FIG. 4, the increase of the collector current Icc accompanied by the temperature increase is prevented.

In this case, the inductance of each of the first inductors L11 to L14 only has to be set such that their impedance is sufficiently higher than the input impedance of the first transistor. For example, when the input impedance thereof is approximately 3Ω at 5 GHz, the inductance of each of the first inductors L11 to L14 is preferably in the order of 1 nH, that is, the reactance X=j30Ω or more.

As mentioned above, according to the embodiment 1, in the vicinity of the first transistors composed of the four HBT cells 11 to 14, the second transistors 21 to 24 constituted by short-circuiting the base and collector port to work as diodes of the temperature-monitoring elements are disposed, and further the first resistors R11 to R14 are disposed between the collector port of the second transistors 21 to 24 and the DC power input port IN2. In this way, even if a rise in temperature due to an increase of the collector current occurs in one of the four HBT cells, for example, the first resistor R11 may render the voltage drop in response to the increase of the collector current of the second transistor 21 constituting the temperature-monitoring element 21. As a result, the voltage of the base of the second transistor 21 may be dropped, and the dropped voltage is applied to the base of the HBT 11, thereby enabling the prevention of the increase of the collector current of the HBT 11. Accordingly, the occurrence of the thermal instability can be efficiently prevented with a comparatively simple circuitry.

Furthermore, because the resistors corresponding to the base ballasting resistors Rb1 to Rb4 of the conventional amplifier circuit (FIG. 7) are not used, the amplifier circuit of the present invention can be achieved with a lower voltage power supply as compared with the conventional technology.

### Embodiment 2

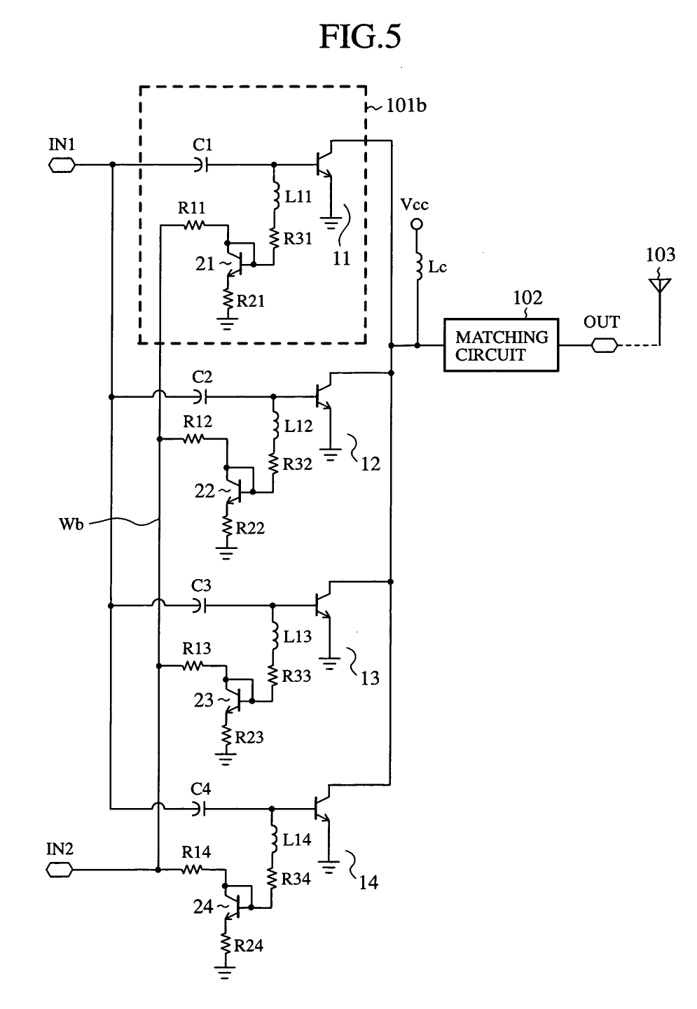

FIG. 5 is a configuration of an amplifier circuit according to embodiment 2 of the present invention. In FIG. 5, reference numeral 101b denotes a power amplifier circuit unit, and reference symbols R31 to R34 represent third resistors each serving as a resistor. Because the other reference numerals and symbols that are the same as those of the embodiment 1 denote the same constituent elements or the corresponding members, these explanations will be omitted. The circuit structure of the embodiment 2 is in effect the same as that of the embodiment 1 except that an inductor and a resistor (third resistor) are connected in series between the base of the HBT cells and the base of the second transistor, thereby providing high impedance elements.

The features of the embodiment 2 will be described below. The value of the third resistor R31 provided within the power amplifier circuit unit 101b, for example, is set to be larger in conjunction with the L11 as compared with the input impedance of the first transistor 11. Also in this case, the value of the resistor R31 can be chosen to be smaller as compared with that of the base ballasting resistor Rb1 of the conventional technology, thus making small the voltage drop in the power circuit, and giving the power amplifier circuit unit advantage in operating with a low power supply voltage.

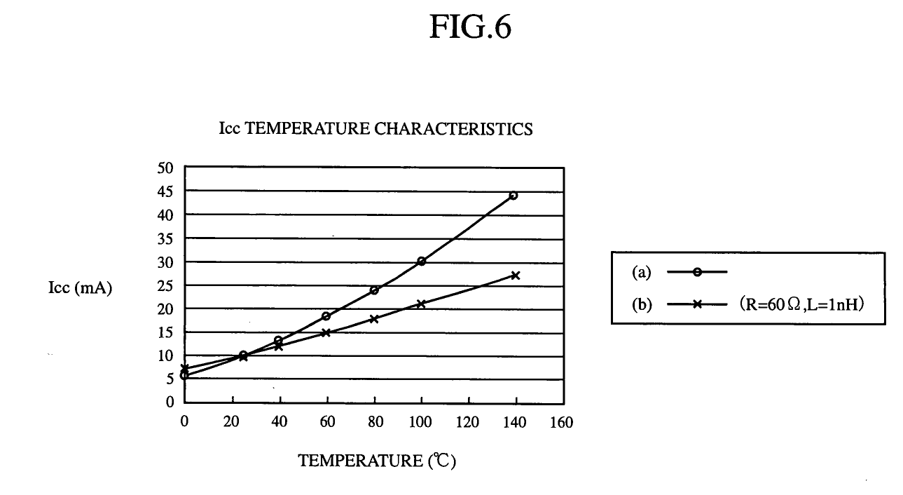

Similarly to FIG. 4, FIG. 6 shows the temperature characteristics of the collector current Icc that flows through the first transistors. FIG. 6 compares the result (a) where no temperature-monitoring elements are used, and the base ballasting resistor is set at 60Ω with the simulation result (b) of the circuit (FIG. 1) in accordance with the embodiment 2, where the second transistors 21 to 24 of the temperature-monitoring elements 21 to 24 for which the first inductors L11 to L14 and the third resistors R31 to R34 are disposed, respectively, are provided in the vicinity of the first transistors 11 to 14, respectively. In this simulation, in order to make out the difference in the temperature compensating effect, each value of the third resistors R31 to R34 is set to 60Ω, which is the same as that of the base ballasting resistors Rb1 to Rb4 of the conventional technology.

As is apparent from the results shown in FIG. 6, also in this case, the circuit of the embodiment 2 such that the second transistors are adjoined to the first transistors may function to prevent the increase of the collector current Icc more efficiently than the conventional amplifier circuit (FIG. 7). In this way, the collector current Icc can be prevented from concentrating in the HBT among the plurality of HBT cells provided therein, thereby preventing the thermal instability and stabilizing the operation of the whole circuit.

As mentioned above, according to the embodiment 2, similarly to the embodiment 1, the second transistors, which are the temperature-monitoring elements 21 to 24 arranged in the vicinity of the first transistors and thermally coupled therewith, have the property of reducing the base voltage of the second transistors by the first resistors R11 to R14, even if the temperature rise is caused by the increase of the collector current in the first transistor. For this reason, the reduced voltage is applied to the base thereof, thereby enabling the increase of the collector current of the first transistor to be prevented. Accordingly, the comparatively simple circuit structure can efficiently prevent the occurrence of the thermal instability in the amplifier circuit.

In addition, in the above description, each of the second transistors serving as the temperature-monitoring elements 21 to 24 is arranged as the diode in such a manner that a bipolar transistor such as an HBT of which the collector and the base are short-circuited. However, the second transistor is not limited to such a diode, but a standard diode may be simply applied to the temperature-monitoring element.

Further, in the embodiments 1 and 2, the circuit structure in which the high impedance element of the power amplifier circuit unit 101a or 101b is constructed of only the first inductor L11, or both the first inductor L11 and the third resistor R31 that are connected in series was described; however, the high impedance element can be also constructed of a resistive element only.

### INDUSTRIAL APPLICABILITY

As mentioned above, in the semi-conductor circuit according to the present invention, even if the one HBT 11 of the plurality of HBT cells 11 to 14 rises in temperature, caused by the increase of the collector current, the first resistor R11 brings about the voltage drop by coping with the increase of the collector current of the second transistor 21 constituting the temperature-monitoring element. This reduces the voltage of the base thereof, and enables the increase of the collector current of the HBT 11 to be prevented, thus enabling the comparatively simple circuit structure to efficiently prevent the occurrence of the thermal instability in the amplifier circuit.

1. A semi-conductor circuit comprising:
a plurality of first transistors, connected in parallel, for amplifying an RF signal; and
a plurality of diodes, which are respectively located in the vicinity of said first transistors under the substantially same temperature, and through which the currents increase as the temperature rises;
wherein the anode of said diode is connected with a DC power supply through a first resistor, while the cathode of the diode is connected to the ground through a second resistor, and said anode controls the collector current of said first transistor by a connection with the base of said first transistor.

2. A semi-conductor circuit according to claim 1, wherein said diode is constructed of a second transistor the collector and the base of which are connected to each other.

3. A semi-conductor circuit according to claim 1, wherein said first transistor and the second transistor are hetero-junction bipolar transistors.

4. A semi-conductor circuit according to claim 1, wherein the base of said first transistor and the anode of said diode are connected through an element having a high impedance at the frequency of said RF signal.

5. A semi-conductor circuit according to claim 2, wherein the base of said first transistor and the base of said second transistor are connected through an element having a high impedance at the frequency of said RF signal.

6. A semi-conductor circuit according to claim 4, wherein said element having a high impedance is an element selected from the group consisting of an inductor, a resistor, and an inductor connected in series with a resistor.

7. A semi-conductor circuit according to claim 2, wherein said first transistor and the second transistor are hetero-junction bipolar transistors.

8. A semi-conductor circuit according to claim 5, wherein said element having a high impedance is an element selected from the group consisting of an inductor, a resistor, and an inductor connected in series with a resistor.
